(19) United States
(12) Patent Application Publication
(10) Pub. No.: US 2025/0355036 A1
(43) Pub. Date: Nov. 20, 2025

(54) METHOD, APPARATUS AND SYSTEM FOR MONITORING ULTRA-HIGH FREQUENCY PARTIAL DISCHARGE OF HYDRO-GENERATOR

(71) Applicant: China Energy Science and Technology Research Institute Co., Ltd., Nanjing (CN)

(72) Inventors: Kunlong Song, Nanjing (CN); Yufeng Hu, Nanjing (CN); Sheng Yang, Nanjing (CN); Dong Yang, Nanjing (CN); Deming Guo, Nanjing (CN); Maoyi Sun, Nanjing (CN); Wenqi Wang, Nanjing (CN); Feng Gao, Nanjing (CN); Haibo Zhao, Nanjing (CN); Teng Fu, Nanjing (CN); Yunping Liu, Nanjing (CN); Ze Huang, Nanjing (CN); Jinlin Liu, Nanjing (CN); Rui Huang, Nanjing (CN); Zhiliang Chen, Nanjing (CN); Haiping Wang, Nanjing (CN); Kefeng Zhang, Nanjing (CN); Xianhui Li, Nanjing (CN); Lixiao Zhu, Nanjing (CN)

(21) Appl. No.: 19/000,858

(22) Filed: Dec. 24, 2024

(30) Foreign Application Priority Data
May 20, 2024 (CN) 202410622803.4
May 20, 2024 (CN) 202410622808.7

(51) Int. Cl. G01R 31/12

(52) U.S. Cl. CPC G01R 31/1263

(57) ABSTRACT

The present disclosure provides a method, apparatus and system for monitoring ultra-high frequency partial discharge of a hydro-generator, and belongs to the technical field of hydro-generator partial discharge monitoring. The method includes: cleaning a partial discharge pulse sequence using a cleaning threshold to obtain a valid pulse sequence; performing redundant data filtering on each data unit divided from the valid pulse sequence to obtain a first target pulse sequence for short-period partial discharge monitoring; determining sub-sequences that are partial discharge events from the valid pulse sequence, forming a second target pulse sequence after associating an amplitude statistical feature of the sub-sequences, and storing the second target pulse sequence. The aforementioned method combines data cleaning, redundant data filtering, and partial discharge event identification, which enhances the real-time performance of partial discharge monitoring and records the long-period partial discharge change trend. The corresponding system adopts a multi-buffer zone and multi-processor architecture, thus further improving the real-time performance of partial discharge monitoring.

### CROSS REFERENCE TO RELATED APPLICATIONS

This application claims the rights of the Chinese Patent Application 202410622808.7, filed on May 20, 2024, and the Chinese Patent Application 202410622803.4, filed on May 20, 2024, the contents of both of which are incorporated herein by reference.

### FIELD OF THE INVENTION

The present disclosure belongs to the technical field of hydro-generator partial discharge monitoring, and particularly relates to a method, apparatus and system for monitoring ultra-high frequency partial discharge of a hydro-generator.

### BACKGROUND OF THE INVENTION

The partial discharge testing of hydro-generators is of great importance. The current engineering methods mainly include: offline partial discharge testing and real-time partial discharge monitoring. Wherein, offline partial discharge testing in the shutdown state is more accurate, as it is not affected by many interference factors in the operating environment, and the mainstream low-frequency partial discharge technology has been widely applied. However, offline testing can only be conducted when the hydro-generator is shut down, making it impossible to monitor the state of the hydro-generator in real-time, which results in poor timeliness in the insulation diagnosis of stator windings. Real-time partial discharge monitoring can improve the problem of timeliness, but under the current data processing solutions and architectures of real-time partial discharge monitoring equipment, there is still a defect of long analysis time for monitoring results. In order to meet the monitoring requirements of massive partial discharge data, there is an urgent need to improve the current data processing solutions and architectures of real-time partial discharge monitoring equipment.

Meanwhile, the frequency employed by the low-frequency partial discharge technology ranges from 10 kHz to 500 kHz. When applied to the hydro-generator, the monitored test data fluctuates significantly due to interference signals during the generator's operation, leading to difficulties in partial discharge pattern recognition and other problems. Compared to the low-frequency partial discharge technology, the frequency employed by the ultra-high-frequency partial discharge technology ranges from 300 MHz to 3 GHz, which can avoid some external interferences. Therefore, it is also necessary to research and develop real-time partial discharge monitoring equipment for ultra-high-frequency applications.

### SUMMARY OF THE INVENTION

In view of the above, an object of the present embodiments is to provide a method, apparatus and system for monitoring ultra-high frequency partial discharge of a hydro-generator, so as to overcome the technical problem of poor real-time monitoring of the real-time partial discharge monitoring equipment in the prior art.

In order to achieve the above object, a first aspect of the embodiments of the present disclosure provides a method for monitoring ultra-high frequency partial discharge of a hydro-generator, including: acquiring a partial discharge pulse sequence generated after analog-to-digital conversion of a partial discharge signal of the hydro-generator; determining a cleaning threshold based on amplitude distribution of the partial discharge pulse sequence, and cleaning the partial discharge pulse sequence using the cleaning threshold to obtain a valid pulse sequence; performing redundant data filtering on each data unit divided from the valid pulse sequence to obtain a first target pulse sequence for short-period partial discharge monitoring; dividing the valid pulse sequence into a plurality of sub-sequences, determining the sub-sequences that are partial discharge events based on a characteristic of repeated occurrences of a partial discharge value of a same insulation defect, and forming a second target pulse sequence with the sub-sequences determined to be the partial discharge events, wherein the second target pulse sequence is configured to perform long-period partial discharge change trend analysis, and the inside of the second target pulse sequence is labelled with an amplitude statistical feature of the internal sub-sequences thereof; and storing the second target pulse sequence.

A second aspect of the embodiments of the present disclosure provides an apparatus for monitoring ultra-high frequency partial discharge of a hydro-generator, including: a data cleaning processor, configured to determine a cleaning threshold based on amplitude distribution of a partial discharge pulse sequence collected by an ultra-high frequency partial discharge sensor, and clean the partial discharge pulse sequence based on the cleaning threshold to obtain a valid pulse sequence; a data synthesis processor, configured to perform redundant data filtering on each data unit divided from the valid pulse sequence to obtain a first target pulse sequence for short-period partial discharge monitoring; divide the valid pulse sequence into a plurality of sub-sequences, determine the sub-sequences that are partial discharge events from the plurality of sub-sequences based on the characteristic of repeated occurrences of a partial discharge value of a same insulation defect, and form a second target pulse sequence with the sub-sequences determined to be the partial discharge events so as to perform long-period partial discharge change trend analysis; and a data storage processor, configured to control a memory connected to the data storage processor to store the second target pulse sequence.

A third aspect of the embodiments of the present disclosure provides a system for monitoring ultra-high frequency partial discharge of a hydro-generator, wherein the system includes: an ultra-high frequency partial discharge sensor, mounted on a stator winding of the hydro-generator, configured to collect a partial discharge signal of the hydro-generator; an analog-to-digital converter, configured to perform analog-to-digital conversion on the partial discharge signal to generate a partial discharge pulse sequence; the aforementioned apparatus, configured to perform data cleaning, data processing and data storage on the partial discharge pulse sequence to obtain a first target pulse sequence for short-period partial discharge monitoring and a second target pulse sequence for long-period partial discharge change trend analysis, and configured to label a partial discharge event; a host computer, configured to perform short-period partial discharge monitoring after acquiring the first target pulse sequence; and a memory, configured to store the labeled partial discharge event.

Other features and advantages of embodiments of the present disclosure will be described in detail in the Detailed Description section that follows.

### BRIEF DESCRIPTION OF DRAWINGS

The accompanying drawings are included to provide a further understanding of embodiments of the disclosure and constitute a part of this specification, and together with the detailed description below serve to explain, but not limit, embodiments of the disclosure. In the drawings:

FIG. 1 is a schematic flow chart of a method for monitoring ultra-high frequency partial discharge of a hydro-generator according to an embodiment of the present disclosure;

FIG. 2 is a schematic diagram of data cleaning;

FIG. 3 is a schematic diagram of measured partial discharge data cleaning;

FIG. 4 is a schematic diagram of transmission of a first target pulse sequence and a second target pulse sequence;

FIG. 5 is a schematic diagram of the composition of a system for monitoring ultra-high frequency partial discharge of a hydro-generator according to an embodiment of the present disclosure;

FIG. 6 is a schematic diagram of the composition of a first buffer zone and a second buffer zone;

FIG. 7 is a block diagram of the composition of a multi-processor coordinated monitoring apparatus for ultra-high-frequency partial discharge in a hydro-generator according to an embodiment of the present disclosure;

FIG. 8 is a schematic diagram of the composition of a monitoring data buffer zone and a storage data buffer zone;

FIG. 9 is a schematic diagram of a partial discharge real-time monitoring image; and

FIG. 10 is a schematic diagram of a continuous time period corresponding to a timing task.

### DETAILED DESCRIPTION OF THE EMBODIMENTS

A detailed description of embodiments of the disclosure will now be described with reference to the accompanying drawings. It should be understood that the detailed description described herein is for illustration and explanation of embodiments of the disclosure only, and is not intended to limit the embodiments of the disclosure.

### Method Embodiments

Referring to FIG. 1, the present embodiment provides a method for monitoring ultra-high frequency partial discharge of a hydro-generator, including S110 to S150.

S110: acquiring a partial discharge pulse sequence generated after analog-to-digital conversion of a partial discharge signal of the hydro-generator.

S120: determining a cleaning threshold based on amplitude distribution of the partial discharge pulse sequence, and cleaning the partial discharge pulse sequence using the cleaning threshold to obtain a valid pulse sequence.

In one practical example, the proportion of data cleaning can be varied by adjusting the size of the cleaning threshold.

S130: performing redundant data filtering on each data unit divided from the valid pulse sequence to obtain a first target pulse sequence for short-period partial discharge monitoring.

It should be understood that a short period refers to the relatively short period set for online monitoring of the partial discharge so as to achieve monitoring of insulation faults such as corona, slot discharge and the like. In contrast, monitoring the trend of insulation state changes, such as insulation aging, requires long-term data collection and analysis, e.g., over a period of years, i.e., long-term monitoring. Therefore, the aforementioned short-term partial discharge monitoring is distinguished from long-term monitoring aimed at tracking the trend of insulation status changes.

It can be seen that the hazard of partial discharge is related to its measured value. Generally, the larger the measured value, the greater the hazard of partial discharge. Furthermore, due to the presence of interference pulses, there is a significant amount of redundant data within each data unit. Therefore, by filtering out the redundant data, the amount of data can be reduced, and the stability of partial discharge monitoring results can be improved.

S140: dividing the valid pulse sequence into a plurality of sub-sequences, determining the sub-sequences that are partial discharge events based on a characteristic of repeated occurrences of a partial discharge value of a same insulation defect, and forming a second target pulse sequence with the sub-sequences determined to be the partial discharge events. Wherein, the second target pulse sequence is configured to perform long-period partial discharge change trend analysis, and the inside of the second target pulse sequence is labelled with an amplitude statistical feature of the internal sub-sequences thereof.

The partial discharge value for the same insulation defect exhibits a characteristic of repeated occurrences. Therefore, in order to identify the partial discharge events within the valid pulse sequence, it is necessary to perform statistical analysis on the amplitude distribution of a plurality of consecutive data units before determining the partial discharge events. Step S140, based on the aforementioned principle, divides the valid pulse sequence into a plurality of sub-sequences, and further removes the redundant data and reduces the amount of data by identifying the partial discharge events.

S150: storing the second target pulse sequence.

Exemplarily, one implementation process of step S120 is as follows: steps S121-S122.

S121: dividing the partial discharge pulse sequence into a plurality of data units at preset time intervals. Wherein, the preset time interval is greater than a time width of at least one partial discharge signal, and each data unit is labeled with an amplitude accumulation feature of an internal partial discharge pulse thereof.

For example, the amplitude accumulation feature can be the average value of the partial discharge pulse amplitudes within the corresponding data unit.

Preferably, the preset time interval is set to lus.

S122: determining a cleaning threshold based on the amplitude accumulation feature, and then cleaning the partial discharge pulse sequence with the cleaning threshold to obtain a valid pulse sequence.

For example, in one specific application, S122 includes sub-steps S122A-S122C as follows:

S122A: determining a cleaning threshold based on the amplitude accumulation feature.

For example, there are differences in the amplitude distribution of partial discharge signals for various installed capacities of hydro-generators. Therefore, it is necessary to determine the differences based on the actual amplitude distribution and utilize a reasonable cleaning threshold to clean the partial discharge pulse sequence.

S122B: if the amplitude accumulation feature of the data unit is greater than or equal to the cleaning threshold, adding a state value label of 1 to the data unit, otherwise adding a state value label of 0 to the data unit.

S122C: removing the data units with the state value label of 0 are removed and forming a valid pulse sequence by the data units with the state value label of 1.

It will be appreciated that in order to achieve an ordered combination of data units with the state value label of 1 into a valid pulse sequence, each data unit should be labeled with its corresponding time value. Thus, the data unit includes three labels, a time value, an amplitude accumulation feature, and a state value.

Exemplarily, one implementation process of step S130 is as follows:
sorting internal partial discharge pulse amplitudes in a descending order for each data unit divided from the valid pulse sequence, and forming a first target pulse sequence by pulse sequences corresponding to top j partial discharge pulse amplitudes within each data unit, wherein, j≤X, X is the maximum number of pulses reserved in each data unit.

For example, the number of pulses in each data unit is 1000, the top 100 pulses are reserved, and the first target pulse sequence is composed of the 100 pulses reserved in each data unit.

Exemplarily, in step S140, the determining the sub-sequences that are partial discharge events based on the characteristic of repeated occurrences of the partial discharge value of the same insulation defect specifically includes the following process:
the amplitude accumulation feature of each data unit in the sub-sequence is compared to an absolute threshold, and it is determined that the sub-sequence is a partial discharge event if the number of data units whose amplitude accumulation feature exceeds the absolute threshold is greater than a first predetermined value.

Exemplarily, in step S140, the amplitude statistical feature includes at least one of a maximum value and an average value of the amplitude accumulation feature within the corresponding sub-sequence.

An application example of the present embodiment will be described below with reference to FIGS. 1 to 4.

In the application example, the following steps S1)-S8) are included:

S1) An ultra-high frequency partial discharge sensor is adopted to collect a partial discharge signal of the stator winding of the hydro-generator, the partial discharge signal is an analog signal F₁(t), t∈[0, T], and in a time period T, the value range of F₁(t) is [−|Vₘᵢₙ|, |Vₘₐₓ|], |Vₘᵢₙ| is an absolute value of the minimum voltage value, and |Vₘₐₓ| denotes an absolute value of the maximum voltage value.

S2) Due to the fact that an ultra-high-frequency analog-to-digital conversion circuit cannot tolerate the high voltage in general, the typical input voltage range of the ultra-high-frequency analog-to-digital conversion circuit is within [−1V, 1V]. Therefore, after the partial discharge signal is collected, a conditioning circuit gain factor K is set to condition the partial discharge signal, so that the testing range of the ultra-high-frequency analog-to-digital conversion circuit is satisfied.

Wherein, the value of K is taken as follows:

$$K = \{ \begin{matrix}\vert {V}_{max} \vert , & if : \vert {V}_{max} \vert > \vert {V}_{min} \vert \\ \vert {V}_{min} \vert , & if : \vert {V}_{min} \vert > \vert {V}_{max} \vert\end{matrix} ;$$

the partial discharge signal after conditioning is denoted as:

$${F}_{2} ( t ) = \frac{1}{K} \times {F}_{1} ( t ) , t ∈ [ 0 , T ] ;$$

S3) Analog-to-digital conversion is performed on the conditioned partial discharge signal at a sampling rate of 1 GHz. Within a time period T, F₂(t) is converted into M discrete sample points, thus forming a partial discharge pulse sequence f₂(n)=DIS(F₂(t)), n=1, 2, . . . M, M=T×10⁹, wherein DIS( ) denotes an equal-distance discretization function.

S4) The partial discharge pulse sequence is cleaned according to the set cleaning threshold.

With a preset time interval of Δt=1 μs, the partial discharge pulse sequence f₂(n) is divided into m data units. The m data units are denoted as: f₂=[f₂₁, f₂₂, . . . f₂ₘ], wherein f₂₁ is the first data unit, f₂₂ is the second data unit, and so on, f₂ₘ is the m-th data unit;

$$m = \frac{T}{Δ t} .$$

Each data unit contains the same number of pulses, denoted by α, and

$$α = \frac{M}{m} .$$

The i-th data unit is denoted by f₂ᵢ. A cleaning threshold Th is set, and three label values for this data unit are calculated: the time value μᵢ, the amplitude accumulation feature τᵢ, and the state value λᵢ, which are denoted by η₂ᵢ as follows:

$${η}_{2 i} = \{ \begin{matrix}{μ}_{i} = ( i - 1 ) Δ t , & time value \\ {τ}_{i} = \frac{{\sum }_{k = 1}^{a} {f}_{2 i} ( k )}{α} , & amplitude accumulation feature \\ {λ}_{i} = \{ \begin{matrix}1 , & if : {τ}_{i} \geq Th \\ 0 , & if : {τ}_{i} < Th\end{matrix} , & state value\end{matrix}$$

Each pulse within a data unit f₂ᵢ is denoted as: f₂ᵢ(k)=f₂(n), k=1, 2, . . . α; n=(i−1)α+1, (i−1)α+2, . . . αi, and k is the number of the pulse within the data unit.

The top three bits of the data unit are set as label bits, and the above three label values are written in sequence, so the data unit f₂ᵢ is denoted as f₂ᵢ(k)=[μᵢ, τᵢ, λᵢ, f₂(n)], k=1, 2, . . . α+3; n=(i−1)α+1, (i−1)α+2, . . . αi;

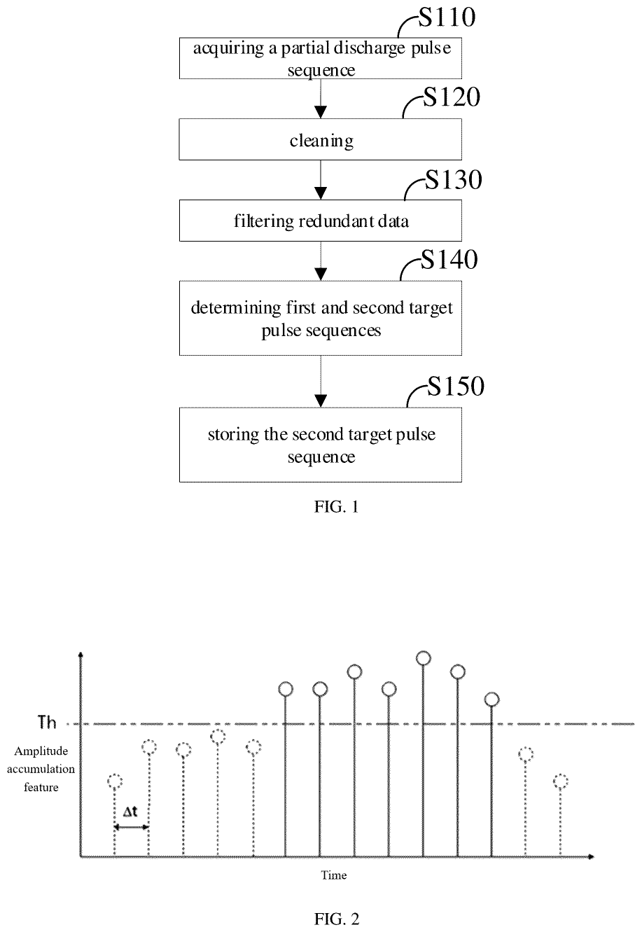

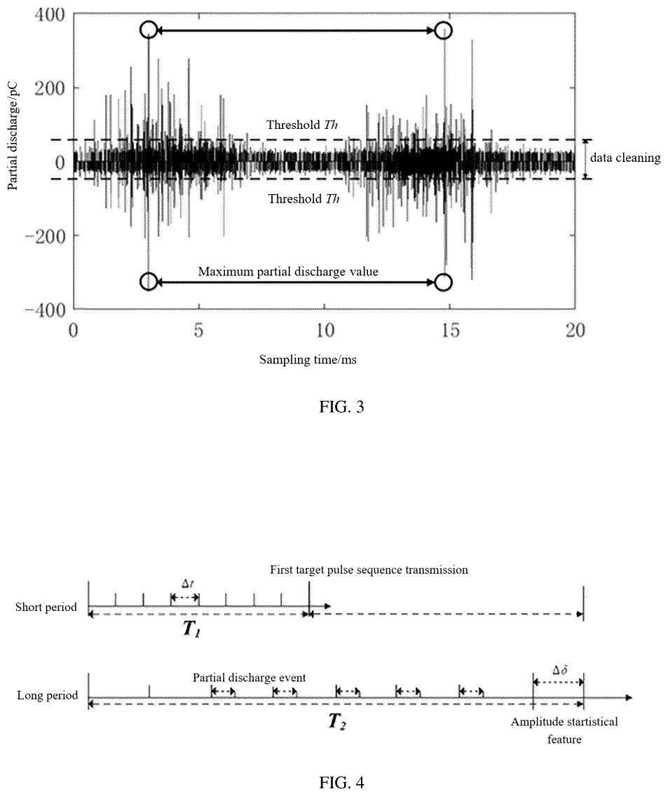

As shown in FIGS. 2 and 3, the data units with the state value of 0 are removed, and those with a state value of 1 are reserved. The reserved data units with the state value of 1 form the valid pulse sequence to complete the data cleaning. A digital signal f₂ of m data units is transformed into a valid pulse sequence f₃ containing m₁ data units after cleaning, f₃=[f₃₁, f₃₂, . . . f₃ₘ_{₁}]. For example, the cleaning proportion is 1%, wherein f₃₁ denotes the first data unit in the cleaned f₃, f₃₂ denotes the second data unit in the cleaned f₃, and so on, and f₃ₘ_{₁} denotes the m₁-th data unit in the cleaned f₃.

S5) The valid pulse sequence f₃ is copied into two identical sets of data.

S6) One set of the valid pulse sequence is read to generate the short-period partial discharge monitoring data.

The short period T₁ is set to 1 s.

For each data unit in the valid pulse sequence within the short period T₁, the 100 pulses with the top 100 amplitudes among its 1000 pulses are selected.

The top 100 pulses of each data unit collectively form the first target pulse sequence.

S7) The first target pulse sequence is uploaded to equipment such as the host computer for waveform display, with the horizontal axis representing time and the vertical axis representing pulse amplitude. Step S6) is repeated in the next T₁ period to achieve real-time display of the short-period partial discharge monitoring data.

S8) Another set of valid pulse sequence is read to perform generation of long-period partial discharge change trend data, and high-speed storage is performed through a disk array or the like for conducting long-period partial discharge change trend analysis.

The long period T₂ is set to 10 min.

The sub-sequences within the valid pulse sequence are divided by time intervals of 3 s, resulting in a total of 200 sub-sequences to be evaluated.

The absolute threshold is set to 300 mV and the first preset value is 50.

The amplitude accumulation feature of each data unit within a certain sub-sequence is compared to an absolute threshold, and if the number of data units exceeding the absolute threshold is greater than 50, the sub-sequence is evaluated as a partial discharge event.

The maximum and minimum values of the amplitude accumulation feature within the sub-sequence evaluated as the partial discharge event are calculated as the amplitude statistical feature, which is marked during the last Δδ time interval of the long period T₂. The value of Δδ is set to 10 ms. After marking the amplitude statistical feature on the sub-sequences corresponding to the identified partial discharge events within the long period, a second target pulse sequence is formed.

The second target pulse sequence is stored at high speed to a storage medium such as a disk array and can be read for waveform observation when partial discharge change trend monitoring is required, the horizontal axis represents time and the vertical axis represents the maximum or minimum value in the aforementioned labeled amplitude statistical feature.

Through the above technical solutions, the beneficial effects brought by the embodiments of the present disclosure mainly include:

1) The time width of the partial discharge signal is generally less than 1 μs, and the partial discharge signal exhibits a multi-peak characteristic. Therefore, the predetermined time interval may be set accordingly, the partial discharge pulse sequence may be divided into a plurality of data units according to the predetermined time interval, and the cleaning threshold may be determined by the amplitude distribution characteristic of the data units, thereby filtering out impulse interference and reducing the amount of data. Further, in the prior art, after the partial discharge signal is collected, the partial discharge signal is stored using a high-speed memory, and then the partial discharge signal is collected from the high-speed memory by a partial discharge analysis system according to a set trigger mechanism for analysis. The embodiment of the present disclosure sets two time periods, respectively a short period and a long period, extracts data from the valid pulse sequence for short-period partial discharge monitoring, and extracts data from the valid pulse sequence for long-period partial discharge change trend analysis and stores the data. Also, the removal of a large amount of redundant data is incorporated in the data extraction process. By combining the above multiple means, the problem of real-time analysis of massive-partial discharge data is solved, the partial discharge long-term change trend data is recorded, and real-time monitoring of partial discharge of the hydro-generator is achieved.

2) Ultra-high frequency is in the range from 300 MHz to 3 GHz, compared to low and high frequencies, the adoption of ultra-high frequency partial discharge monitoring technology can effectively avoid external interference, thus enhancing the anti-interference capability of real-time partial discharge monitoring of the hydro-generator and improving the stability of the partial discharge monitoring result.

### Apparatus Embodiments

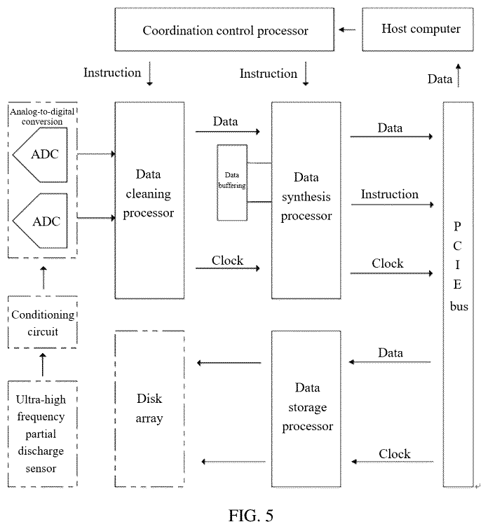

Referring to FIG. 5, an embodiment of the present disclosure provides an apparatus for monitoring ultra-high frequency partial discharge of a hydro-generator, including: a data cleaning processor, configured to determine a cleaning threshold based on amplitude distribution of a partial discharge pulse sequence collected by an ultra-high frequency partial discharge sensor, and clean the partial discharge pulse sequence based on the cleaning threshold to obtain a valid pulse sequence; a data synthesis processor, configured to perform redundant data filtering on each data unit divided from the valid pulse sequence to obtain a first target pulse sequence for short-period partial discharge monitoring, divide the valid pulse sequence into a plurality of sub-sequences, determine sub-sequences that are partial discharge events from the plurality of sub-sequences based on the characteristic of repeated occurrences of a partial discharge value of a same insulation defect, and form a second target pulse sequence with the sub-sequences determined to be the partial discharge events to perform long-period partial discharge change trend analysis; and a data storage processor, configured to control a memory connected to the data storage processor to store the second target pulse sequence. Wherein, the memory is a disk array in FIG. 5.

Preferably, in the data synthesis processor, a first task of obtaining the first target pulse sequence and a second task of obtaining the second target pulse sequence are executed in parallel, and the parallel execution includes writing the valid pulse sequence from a first data buffer zone and a second data buffer zone in which the valid pulse sequence is stored, respectively, for data processing.

For example, the data synthesis processor executes the first task and the second task in parallel. The first task involves writing the valid pulse sequence, filtering out redundant data from each data unit divided from the valid pulse sequence, and obtaining the first target pulse sequence. The second task involves writing the valid pulse sequence, dividing the valid pulse sequence into a plurality of sub-sequences, determining sub-sequences that are partial discharge events based on a characteristic of repeated occurrences of a partial discharge value of a same insulation defect, and forming the second target pulse sequence with the sub-sequences that are partial discharge events.

In this regard, the real-time performance of the hydro-generator partial discharge monitoring is improved by the parallelization of the first task and the second task, in combination with threshold cleaning, redundant data filtering, and partial discharge event identification means.

More preferably, the data synthesis processor is connected with a first data buffer zone and a second data buffer zone, each of the first data buffer zone and the second data buffer zone is configured to buffer the valid pulse sequence. The first task is configured to write the valid pulse sequence from the first data buffer zone and the second task is configured to write the valid pulse sequence from the second data buffer zone.

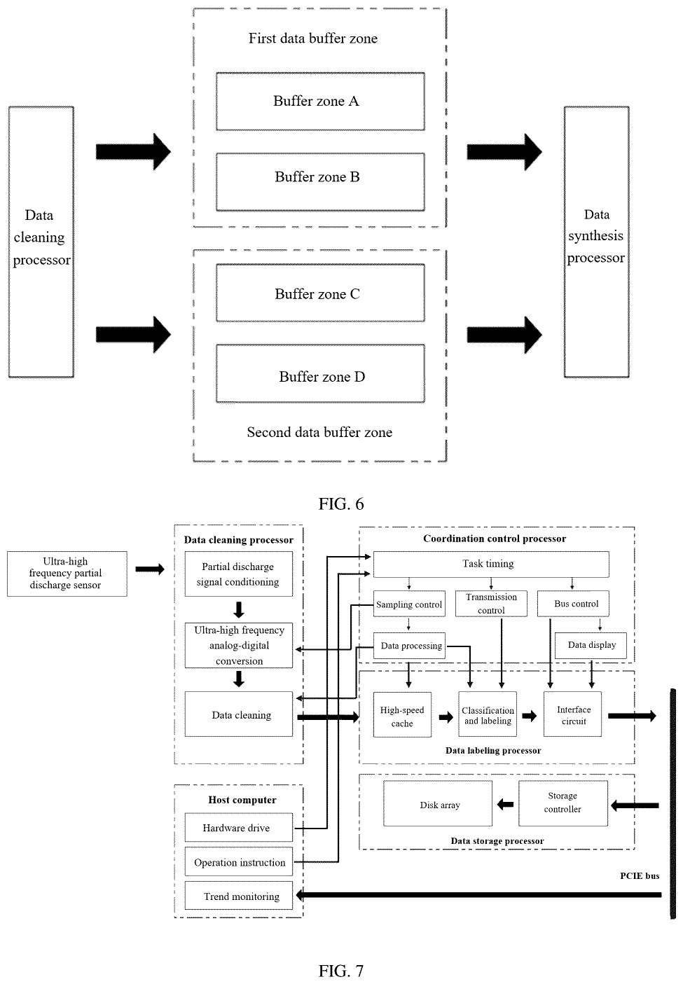

In an example, referring to FIG. 6, the first data buffer zone includes a buffer zone A and a buffer zone B. The valid pulse sequence is stored in the buffer zone A, and when the buffer zone A is full, the write data interface is switched to the buffer zone B, while the processor reads data from the buffer zone A.

The second data buffer zone includes a buffer zone C and a buffer zone D. The valid pulse sequence is stored in the buffer zone C, and when the buffer zone C is full, the write data interface is switched to the buffer zone D, while the data synthesis processor reads data from the buffer zone C.

For the first data buffer zone and the second data buffer zone, both the write pointer and the read pointer are switched between the two buffer zones inside themselves, thus speeding up the write and read rates of the valid pulse sequence, and improving the real-time performance of partial discharge monitoring.

Further, in the process of realizing the above apparatus embodiment, the inventors of the present application found that: the main technical difficulty of the ultra-high frequency partial discharge monitoring technology lies in the problem of real-time processing of massive partial discharge data. For example, without loss of generality, the partial discharge online monitoring equipment collects a partial discharge signal from the partial discharge sensor at a sampling frequency of 1 GHz with a sampling accuracy of 16 bit, and a single-channel data flow typically reaches 2 GB/s. The partial discharge online monitoring equipment determines its number of collecting channels according to the type of processor it adopts, usually contains 8-12 collecting channels. When there are 8 collecting channels, the real-time data processing volume reaches 16 GB/s. At this point, online partial discharge monitoring equipment with a single processor is hard to meet the real-time processing requirement for massive data.

Accordingly, referring to FIG. 7, a preferred embodiment of the present disclosure provides a multi-processor coordinated monitoring apparatus for ultra-high-frequency partial discharge of a hydro-generator, and the apparatus includes a coordination control processor, a data cleaning processor, a data labeling processor and a data storage processor.

Wherein, the coordination control processor is configured to, in response to a partial discharge monitoring operation instruction sent by the host computer, establish timing tasks, wherein each timing task occupies a continuous time period, and within each timing task, sequentially execute preprocessing control, classification and labeling control, and transmission control for a partial discharge signal.

Wherein, the data cleaning processor is configured to receive the partial discharge signal from outside and preprocess the partial discharge signal based on a preprocessing instruction issued by the coordination control processor within the current timing task to obtain a first data unit. For example, the partial discharge signal of the hydro-generator stator winding is collected via an ultra-high frequency partial discharge sensor, and the data cleaning processor receives the partial discharge signal from the ultra-high frequency partial discharge sensor.

Wherein, the data labeling processor is configured to apply a label characterizing a partial discharge statistical feature to the first data unit based on a classification and labeling instruction issued by the coordination control processor within the current timing task, when the first data unit triggers a threshold condition of the partial discharge event, apply a label characterizing partial discharge event feature information to the current partial discharge event, after labeling, transmit the labeled first data unit to the host computer based on a transmission control instruction issued by the coordination control processor within the current timing task to enable the host computer to perform partial discharge change trend analysis, and transmit the labeled partial discharge event to the data storage processor when a threshold condition for the partial discharge event is triggered.

Wherein, the data storage processor is configured to store the labeled partial discharge event in the memory connected to it.

To perform trend analysis of the partial discharge through the host computer, the label characterizing the partial discharge statistical feature is applied to the preprocessed first data unit. The label can reflect the overall statistical feature of the partial discharge of the first data unit. It can be seen that in the monitoring of the insulation fault state of the stator winding in the hydro-generator, collecting the maximum amplitude of the partial discharge within a certain time period allows for better observation of changes in the insulation state of the stator winding. Therefore, in a specific example, the label characterizing the partial discharge statistical feature include the maximum partial discharge value.

In an example, the partial discharge event data is typically used to perform visual analysis such as a discharge fingerprint map, and the partial discharge event data typically includes a partial discharge value, the phase, etc. of each partial discharge event. Thus, in one specific example, the label characterizing the partial discharge event feature information includes the partial discharge value, the phase, and the time of occurrence of the partial discharge event.

Partial discharge is periodically repeated for a particular partial discharge type. In this case, when there are partial discharge pulses having an amplitude greater than a certain threshold and the cumulative number of the partial discharge pulses having an amplitude greater than the certain threshold is greater than the certain threshold, then the partial discharge event in the partial discharge pulse sequence may be identified. Based on this principle, one of ordinary skill in the art may be aware of one or more possible threshold conditions to trigger the partial discharge event.

For example, in one specific example, the first data unit is a partial discharge pulse sequence composed of partial discharge pulses, and the threshold condition of the partial discharge event is triggered when the number of partial discharge pulses having an amplitude greater than a first threshold is greater than a second threshold. The first threshold and the second threshold may be differentially set according to different hydro-generator models, and the specific values of the first threshold value and the second threshold value are not limited in this embodiment.

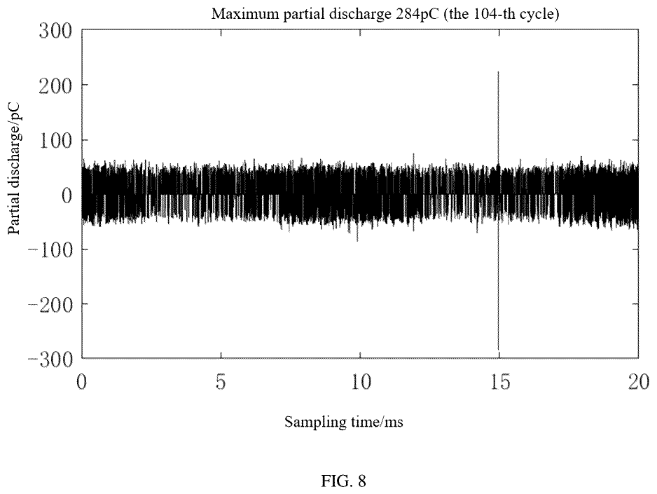

It should be understood that the continuous time period for each timing task may be set according to the real-time requirements of the partial discharge change trend analysis of the host computer and the specific choice of the coordination control processor, the data cleaning processor, and the data labeling processor. FIG. 8 shows a real-time monitoring image of the partial discharge displayed by the host computer with a set time interval of 20 ms (one power frequency cycle). That is, all monitoring data is transmitted to the host computer for display every 20 ms to observe the partial discharge waveform. Additionally, the label characterizing the partial discharge statistical feature can be recorded, for example, only the maximum partial discharge value within each 20 ms interval is saved. As shown in FIG. 8, the recorded maximum partial discharge value within the current 20 ms interval is 284 pC.

As can be seen, the partial discharge signal received from, for example, the ultra-high frequency partial discharge sensor contains much redundant data. Thus, the pre-processing on the partial discharge signal by the data cleaning processor may include data cleaning or the like. In one specific example, the pre-processing on the partial discharge signal by the data cleaning processor includes signal conditioning, analog-to-digital conversion, and redundant data cleaning. For example, the cleaning threshold may be set by a change in amplitude of the partial discharge magnitude, and the partial discharge pulses having an amplitude that does not exceed the cleaning threshold may be removed. After data cleaning, the amount of data for subsequent data processing and transmission is greatly reduced, thus reducing hardware configuration costs for the data labeling processor and the like.

In the above technical solution, the first data unit is transmitted to the host computer for partial discharge change trend analysis without storage after being applied with the label characterizing the partial discharge statistical feature. Thus, the first data unit after being applied with the label characterizing the partial discharge statistical feature may be referred to as monitoring data, and the labeled partial discharge event is stored in the memory for use in subsequent long-period determination of the insulation state of the hydro-generator stator winding, so that the partial discharge event applied with the label characterizing the partial discharge event feature information can be referred to as storage data. Because there is a real-time requirement for the monitoring data, while the storage data is stored under a trigger condition, there is no real-time requirement. Therefore, to enhance the real-time delivery of the monitoring data to the host computer, the following example proposes a data partitioning storage solution.

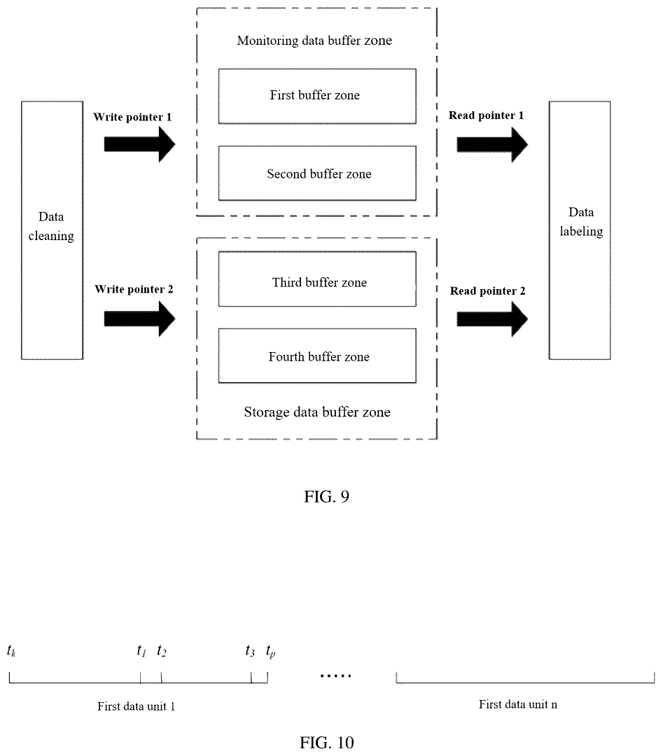

Specifically, as shown in FIG. 9, the data labeling processor includes two buffer zones, namely a monitoring data buffer zone and a storage data buffer zone.

Wherein, the monitoring data buffer zone is configured to write a first data unit output from the data cleaning processor, and the data labeling processor reads the first data unit from the monitoring data buffer zone upon applying a label characterizing a partial discharge statistical feature to the first data unit based on a classification and labelling instruction issued by the coordination control processor within the current timing task.

Wherein, the storage data buffer zone is configured to write a first data unit output from the data cleaning processor, the data labeling processor determines the partial discharge event from the first data unit read from the storage data buffer zone upon applying a label characterizing partial discharge event feature information to the current partial discharge event based on a classification and labelling instruction issued by the coordination control processor within the current timing task.

As an improvement to the aforementioned data partitioning storage solution, in a specific embodiment, as shown in FIG. 9, the monitoring data buffer zone includes a first buffer zone and a second buffer zone. The first buffer zone and the second buffer zone share a read pointer and a write pointer, e.g., the read pointer 1 and the write pointer 1 shown in FIG. 9. During the switching of timing tasks, the direction of the write pointer is switched between the first buffer zone and the second buffer zone, and the direction of the read pointer is switched between the first buffer zone and the second buffer zone. For example, under the current timing task, the write pointer points to the first buffer zone and the read pointer points to the first buffer zone. After the current timing task is completed and before the next timing task arrives, the direction of the write pointer is switched to the second buffer zone and the direction of the read pointer is switched to the second buffer zone.

As an improvement to the aforementioned data partitioning storage solution, in a specific embodiment, as shown in FIG. 9, the storage data buffer zone includes a third buffer zone and a fourth buffer zone. The third buffer zone and the fourth buffer zone share a read pointer and a write pointer, e.g., the read pointer 2 and the write pointer 2 shown in FIG. 9. During the switching of timing tasks, the direction of the write pointer is switched between the third buffer zone and the fourth buffer zone, and the direction of the read pointer is switched between the third buffer zone and the fourth buffer zone. For example, under the current timing task, the write pointer points to the third buffer zone and the read pointer points to the third buffer zone. After the current timing task is completed and before the next timing task arrives, the direction of the write pointer is switched to the fourth buffer zone and the direction of the read pointer is switched to the fourth buffer zone.

By partitioning inside the monitoring data buffer zone and the storage data buffer zone and the settings of the two read pointers and the two write pointers, the efficiency of data transmission and processing is improved, thereby enhancing the real-time performance of ultra-high-frequency partial discharge monitoring of the hydro-generator.

Exemplarily, the data labeling processor is communicatively connected with the data storage processor and the host computer, respectively, via a PCIE bus.

The timing task established by the coordination control processor is divided into two tiers when the pre-processing includes signal conditioning, analog-to-digital conversion and data cleaning, and the data labeling processor is communicatively connected with the data storage processor and the host computer, respectively, via the PCIE bus. The first tier executes sampling control, transmission control and bus control on the partial discharge signal in a timing sequence, and the second tier is configured to issue a link establishment instruction, a display communication setup instruction and a data display instruction under bus control and a data cleaning instruction, a classification and labeling instruction and a data caching instruction under sampling control when the timing task is executed.

Wherein, within the current timing task:
the data cleaning processor is configured to perform analog-to-digital conversion on the partial discharge signal based on a sampling control instruction to obtain a partial discharge pulse sequence, and after analog-to-digital conversion, perform data cleaning on the partial discharge pulse sequence based on a data cleaning instruction to obtain a first data unit.

The data labeling processor is configured to write the first data unit to the monitoring data buffer zone and the storage data buffer zone based on the data caching instruction, then read the first data unit cached within the monitoring data buffer zone based on the classification and labeling instruction, apply a label characterizing a partial discharge statistical feature to the first data unit, and read the first data unit cached within the storage data buffer zone based on the classification and labeling instruction, and apply a label characterizing partial discharge event feature information to the current partial discharge event when the first data unit triggers a threshold condition for the partial discharge event.

The data labeling processor is configured to perform data preparation for the labeled first data unit to be transmitted and the labeled partial discharge event based on the transmission control instruction; after data preparation, establish a PCIE bus transmission link with the host computer and the data storage processor via an internal bus interface circuit inside based on the link establishment instruction; establish communication with the host computer via a data display interface circuit inside based on the display communication setup instruction; and transmit, via a data display interface circuit, the labeled first data unit to the host computer for partial discharge change trend analysis and display based on the data display instruction.

Exemplarily, the coordination control processor employs an ARM module, and the data cleaning processor, the data labeling processor, and the data storage processor all employ FPGA modules.

To enhance the scalability of the multi-processor coordinated monitoring apparatus for ultra-high-frequency partial discharge of the hydro-generator provided in the aforementioned embodiment, in a specific embodiment, a continuous time period occupied by each timing task is provided with a dormancy period. During subsequent functional expansions, the dormancy period can be utilized to apply other labels characterizing the partial discharge statistical feature to the first data unit, or to improve the existing labels characterizing the partial discharge statistical feature.

Still further, in conjunction with FIG. 10, the coordination control processor is further configured to perform the following steps SS1-SS8 to implement the multi-processor coordinated monitoring method for ultra-high-frequency partial discharge of the hydro-generator.

Step SS1, performing initialization and hardware drive loading in response to the partial discharge monitoring operation instruction of the host computer.

Step SS2, establishing timing tasks. The timing task is divided into two tiers, each timing task occupying one continuous time period. One continuous time period is denoted as tₖ˜tₚ, wherein, tₖ denotes a starting moment of partial discharge signal preprocessing, tₚ denotes the moment when the labeled first data unit is displayed by the host computer, t₁, t₂ and t₃, in turn, are three moments within the continuous time period from tₖ to tₚ, and t₁<t₂<t₃. The first tier of timing task is performed in a timing sequence. Within one timing task, sampling control, transmission control and bus control are executed on the partial discharge signal in sequence. The second tier of the timing task is configured to issue a link establishment instruction, a display communication setup instruction and a data display instruction under bus control and a data cleaning instruction, a classification and labeling instruction and a data caching instruction under sampling control when the timing task is executed.

Step SS3, during the time period of tₖ˜t₁, issuing a sampling control instruction to a data cleaning processor to enable the data cleaning processor to perform analog-to-digital conversion on the partial discharge signal based on the sampling control instruction to obtain the partial discharge pulse sequence. After analog-to-digital conversion, a data cleaning instruction is issued to the data cleaning processor to enable the data cleaning processor to perform data cleaning on the partial discharge pulse sequence based on the data cleaning instruction to obtain the first data unit, and a data caching instruction is sent to the data labeling processor to enable the data labeling processor to write the first data unit into the monitoring data buffer zone and the storage data buffer zone based on the data caching instruction.

Step SS4, during the time period of t₁˜t₂, issuing the classification and labeling instruction to the data labeling processor to enable the data labeling processor to read the first data unit cached within the monitoring data buffer zone based on the classification and labeling instruction. And, the first data unit is applied with a label characterizing the partial discharge statistical feature, and the first data unit cached within the storage data buffer zone is read based on the classification and labeling instruction. When the first data unit triggers a threshold condition for a partial discharge event, a label characterizing partial discharge event feature information is applied to the current partial discharge event to enable the data storage processor to receive the labeled partial discharge event. Finally, the memory is controlled to store the partial discharge event.

Step SS5, at the t₂ moment, issuing a transmission control instruction the data labeling processor to enable the data labeling processor to perform data preparation for the labeled first data unit to be transmitted and the labeled partial discharge event. At the t₂ moment, a link establishment instruction is issued to the data labeling processor to enable establishment of a PCIE bus transmission link with the host computer and the data storage processor via a bus interface circuit in the data labeling processor. At the t₂ moment, a display communication establishment instruction is issued to the data labeling processor to establish communication with the host computer via a data display interface circuit in the data labeling processor.

Step SS6, during the time period of t₂˜t₃, performing dormancy.

Step SS7, during the time period of t₃˜tₚ, issuing a data display instruction to the data labeling processor to facilitate sending the labeled first data unit to the host computer via the data display interface circuit for partial discharge change trend analysis and display.

Step SS8, steps SS3 to SS8 are repeatedly performed to transmit the plurality of labeled first data units to the host computer.

Exemplarily, the t₁ moment is an intermediate moment of the continuous time period of tₖ˜tₚ.

Exemplarily, the label characterizing the partial discharge statistical feature includes a maximum partial discharge value.

Exemplarily, the label characterizing the partial discharge event feature information includes a partial discharge value, a phase, and a time of occurrence of the partial discharge event.

Exemplarily, the monitoring data buffer zone includes a first buffer zone and a second buffer zone, the first buffer zone and the second buffer zone share a read pointer and a write pointer, the direction of the write pointer and the direction of the read pointer are both switched between the first buffer zone and the second buffer zone during the switching of timing tasks.

Exemplarily, the stored data buffer zone includes a third buffer zone and a fourth buffer zone, the third buffer zone and the fourth buffer zone share a read pointer and a write pointer, and the direction of the write pointer and the direction of the read pointer are both switched between the third buffer zone and the fourth buffer zone during the switching of timing tasks.

Exemplarily, the threshold condition of the partial discharge event is triggered when the number of partial discharge pulses having an amplitude greater than a first threshold is greater than a second threshold.

In summary, a total of four edge-end processors are provided in the apparatus of FIG. 7, respectively are a data cleaning processor, a data labeling processor, a data storage processor and a coordination control processor, and each processor is an independent data processing center, and the four processors collectively perform operations such as signal processing, data transmission and real-time signal control in the ultra-high frequency partial discharge monitoring process of the hydro-generator. Wherein, the coordination control processor is a control center within the apparatus, which interfaces the host computer and other processors, the multi-processor mode improves the data processing speed, and thus realizes the real-time performance of the ultra-high frequency partial discharge monitoring.

In addition, the processed partial discharge signals are classified and labeled. One category is monitoring data, which has a large volume and is only transmitted to the host computer for analysis of the partial discharge change trend after being labeled to characterize the partial discharge statistical feature, and is not stored. The other category is storage data, which only includes partial discharge event data under a triggering mechanism and is stored. Compared to fully storing the processed partial discharge signals and then reading them from the storage structure based on a set triggering mechanism for partial discharge fault monitoring and analysis of the hydro-generator, the monitoring solution corresponding to the apparatus in FIG. 7 further improves the real-time performance of monitoring and analysis.

More implementation details and advantageous effects of the apparatus embodiments can refer to the above method embodiments, which will not be described in detail here.

### System Embodiments

Referring to FIGS. 5 and 7, the present embodiment provides a system for monitoring ultra-high frequency partial discharge of a hydro-generator, including an ultra-high frequency partial discharge sensor, an analog-to-digital converter, the above-described apparatus for monitoring ultra-high frequency partial discharge of a hydro-generator, a host computer and a memory.

Wherein, the ultra-high frequency partial discharge sensor is mounted on a stator winding of the hydro-generator, and is configured to collect a partial discharge signal of the hydro-generator.

Wherein, the analog-to-digital converter is configured to perform analog-to-digital conversion on the partial discharge signal to generate a partial discharge pulse sequence. In FIG. 5, ADC represents an analog-to-digital converter.

Wherein, the apparatus for monitoring ultra-high frequency partial discharge of a hydro-generator refers to the above-described embodiments of the apparatus, which will not be described in detail herein.

Wherein, the host computer is configured to perform short-period partial discharge monitoring after acquiring the first target pulse sequence.

Wherein the memory is configured to store the labeled partial discharge event. Wherein, the memory is, for example, a disk array.

Preferably, with reference to FIG. 5, the conditioning is performed prior to analog-to-digital conversion, so the system is further provided with a conditioning circuit located between the partial discharge sensor and the analog-to-digital converter.

Preferably, with reference to FIG. 5, the data synthesis processor and the data labeling processor are communicatively connected with the data storage processor and the host computer, respectively, via the PCIE bus.

Preferably, the data cleaning processor and the data synthesis processor are selected from high-performance FPGA chips, and for satisfying the sampling frequency of 1 GHz, the FPGA chip of XCKU115 type or the like is used.

Preferably, the coordination control processor is further configured to coordinate and control the function execution of the respective processors, and to coordinate and control data transmission between any two of the respective processors and the host computer. For example, the coordination control processor is responsible for communicating with the host computer, and coordinating the collection of the ultra-high frequency partial discharge sensor, the analog-to-digital conversion of the analog-to-digital converter, the data cleaning of the data cleaning processor, the data processing of the data synthesis processor, the transmission between the data synthesis processor and the data storage processor, and the transmission between the data synthesis processor and the host computer. For example, the coordination control processor is selected from an ARM chip. In addition, the coordination control method executed by the coordination control processor may be designed in combination with the multi-processor coordination control method of the general embodiment to obtain one or more coordination control methods applicable to the present embodiment, which is not overrepresented in this embodiment.

In an example, employing the system for monitoring ultra-high frequency partial discharge of the hydro-generator provided by the embodiment of the present disclosure for partial discharge monitoring can include the following steps ST1-ST7:

Step ST1, the host computer sends a partial discharge monitoring operation instruction to the coordination control processor.

Step ST2, the coordination control processor performs initialization and hardware drive loading based on the partial discharge monitoring operation instruction, and establishes timing tasks, wherein each timing task occupies one continuous time period, each timing task is divided into two tiers, the first tier of the timing task executes sampling control, transmission control and bus control on the partial discharge signal in a timing sequence, a second tier of the timing task is configured to issue a link establishment instruction, a display communication setup instruction and a data display instruction under bus control and a data cleaning instruction, a classification and labeling instruction and a data caching instruction under sampling control when the timing task is executed.

Step ST3, the data cleaning processor receives the partial discharge signal from the outside, and performs analog-to-digital conversion on the partial discharge signal based on a sampling control instruction issued by the coordination control processor within the current timing task to obtain a partial discharge pulse sequence, after analog-to-digital conversion, performs data cleaning on the partial discharge pulse sequence based on a data cleaning instruction to obtain a first data unit, and stores the first data unit into a monitoring data buffer zone and a storage data buffer zone.

Step ST4, the data labeling processor writes the first data unit to the monitoring data buffer zone and the storage data buffer zone based on the data caching instruction, then reads the first data unit cached within the monitoring data buffer based on the classification and labeling instruction, applies a label characterizing a partial discharge statistical feature to the first data unit, and reads the first data unit cached within the storage data buffer based on the classification and labeling instruction, and applies a label characterizing partial discharge event feature information to the current partial discharge event when the first data unit triggers a threshold condition for the partial discharge event.

Step ST5, the system is in dormancy.

Step ST6, the data labeling processor performs data preparation for the labeled first data unit to be transmitted and the labeled partial discharge event based on the transmission control instruction; after data preparation, establishes a PCIE bus transmission link with the host computer and the data storage processor via a bus interface circuit inside based on the link establishment instruction; establishes communication with the host computer via a data display interface circuit inside based on the display communication setup instruction; and transmits, via a data display interface circuit, the labeled first data unit to the host computer for partial discharge change trend analysis and display based on the data display instruction.

Step ST7, after the data storage processor receives the labeled partial discharge event, the data storage processor controls the disk array to store the labeled partial discharge event.

The system embodiments described above are merely illustrative, wherein the units illustrated as separate components may or may not be physically separated, and the components illustrated as units may or may not be physical units, i.e. may be located at one place, or may be distributed over a plurality of network elements. Some or all of the modules may be selected according to actual needs to achieve the object of the embodiment. Those of ordinary skill in the art can understand and implement without inventive effort.

In yet another aspect, the present disclosure also provides a machine-readable storage medium having stored thereon a computer program which, when executed by a processor, implements any one of the methods for monitoring ultra-high frequency partial discharge of a hydro-generator as described in the above method embodiments.

From the above description of the embodiments, it will be clear to those skilled in the art that the embodiments can be implemented by means of software plus a necessary general hardware platform, but of course also by means of hardware. Based on such understanding, the above technical solution in essence or the part contributing to the prior art can be embodied in the form of a software product, the computer software product may be stored in a computer readable storage medium, such as a ROM/RAM, a magnetic disk, an optical disk, or the like, and includes instructions for causing a computer device (which may be a personal computer, a server, a network device, or the like) to perform the methods of the various embodiments or portions of the embodiments.

Finally, it should be described that the above embodiments are only used to illustrate the technical solution of the present disclosure, but not to limit it. Although the present disclosure has been described in detail with reference to the aforementioned embodiments, those skilled in the art should understand that the technical solutions described in the aforementioned embodiments may be modified or some technical features may be equivalently replaced. However, these modifications or substitutions do not deviate the essence of the corresponding technical solutions from the spirit and scope of the technical solutions of the embodiments of the present disclosure.

1. A method for monitoring ultra-high frequency partial discharge of a hydro-generator, comprising:
acquiring a partial discharge pulse sequence generated after analog-to-digital conversion of a partial discharge signal of the hydro-generator;
determining a cleaning threshold based on amplitude distribution of the partial discharge pulse sequence, and cleaning the partial discharge pulse sequence using the cleaning threshold to obtain a valid pulse sequence;
performing redundant data filtering on each data unit divided from the valid pulse sequence to obtain a first target pulse sequence for short-period partial discharge monitoring;
dividing the valid pulse sequence into a plurality of sub-sequences, and determining the sub-sequences that are partial discharge events from the plurality of sub-sequences based on a characteristic of repeated occurrences of a partial discharge value of a same insulation defect, forming a second target pulse sequence with the sub-sequences determined to be the partial discharge events, wherein the second target pulse sequence is configured to perform long-period partial discharge change trend analysis, and the inside of the second target pulse sequence is labelled with an amplitude statistical feature of the internal sub-sequences thereof; and
storing the second target pulse sequence.

2. The method of claim 1, wherein obtaining the valid pulse sequence comprises:
dividing the partial discharge pulse sequence into a plurality of data units at preset time interval, the preset time interval being greater than a time width of at least one partial discharge signal, and each data unit being labeled with an amplitude accumulation feature of an internal partial discharge pulse thereof; and
determining a cleaning threshold based on the amplitude accumulation feature of the data unit, and using the cleaning threshold to clean the partial discharge pulse sequence to obtain a valid pulse sequence.

3. The method of claim 2, wherein the preset time interval is 1 μs.

4. The method of claim 2, wherein obtaining the valid pulse sequence further comprises:
determining a cleaning threshold based on the amplitude accumulation feature of the data unit;
adding a state value label of 1 to the data unit if the amplitude accumulation feature of the data unit is greater than or equal to the cleaning threshold, otherwise adding a state value label of 0 to the data unit; and
removing the data units with the state value label of 0 and forming a valid pulse sequence by the data units with the state value label of 1.

5. The method of claim 2, wherein determining the sub-sequences that are partial discharge events from the plurality of sub-sequences comprises:
comparing the amplitude accumulation feature of each data unit in the sub-sequence to an absolute threshold, and determining that the sub-sequence is a partial discharge event if the number of data units whose amplitude accumulation feature exceeds the absolute threshold is greater than a first predetermined value.

6. The method of claim 2, wherein the amplitude accumulation feature is a mean value of amplitudes of partial discharge pulses within the corresponding data unit, or the amplitude statistical feature comprises at least one of a maximum value and an average value of the amplitude accumulation feature within the corresponding sub-sequence.

7. The method of claim 1, wherein the redundant data filtering comprises:
sorting internal partial discharge pulse amplitudes in a descending order for each data unit divided from the valid pulse sequence, and forming a first target pulse sequence by pulse sequences corresponding to top j partial discharge pulse amplitudes within each data unit, wherein, j≤X, X is the maximum number of pulses reserved in each data unit.

8. An apparatus for monitoring ultra-high frequency partial discharge of a hydro-generator, comprising:
a data cleaning processor, configured to determine a cleaning threshold based on amplitude distribution of a partial discharge pulse sequence collected by an ultra-high frequency partial discharge sensor, and clean the partial discharge pulse sequence based on the cleaning threshold to obtain a valid pulse sequence;
a data synthesis processor, configured to perform redundant data filtering on each data unit divided from the valid pulse sequence to obtain a first target pulse sequence for short-period partial discharge monitoring; divide the valid pulse sequence into a plurality of sub-sequences, determine the sub-sequences that are partial discharge events from the plurality of sub-sequences based on the characteristic of repeated occurrences of a partial discharge value of a same insulation defect, and form a second target pulse sequence with the sub-sequences determined to be the partial discharge events so as to perform long-period partial discharge change trend analysis; and
a data storage processor, configured to control a memory connected to the data storage processor to store the second target pulse sequence.

9. The apparatus of claim 8, wherein the apparatus further comprises a coordination control processor and a data labeling processor;
the coordination control processor is configured to: coordinate and control functional execution of each processor; coordinate and control data transmission between any two of the processors and a host computer; in response to a partial discharge monitoring operation instruction sent by the host computer, establish timing tasks, wherein each timing task occupies a continuous time period, and within each timing task, sequentially execute preprocessing control, classification and labeling control, and transmission control for a partial discharge signal;
the data cleaning processor is further configured to: receive the partial discharge signal and preprocess the partial discharge signal based on a preprocessing instruction issued by the coordination control processor within the current timing task to obtain a first data unit, the first data unit comprising the partial discharge pulse sequence;
the data labeling processor is configured to: apply a label characterizing a partial discharge statistical feature to the first data unit based on a classification and labeling instruction issued by the coordination control processor within the current timing task, when the first data unit triggers a threshold condition of the partial discharge event, apply a label characterizing partial discharge event feature information to the current partial discharge event, after labeling, transmit the labeled first data unit to the host computer based on a transmission control instruction issued by the coordination control processor within the current timing task to enable the host computer to perform partial discharge change trend analysis, and transmit the labeled partial discharge event to the data storage processor; and
the data storage processor is further configured to store the labeled partial discharge event in the memory.

10. The apparatus of claim 9, wherein the label characterizing the partial discharge statistical feature comprises a maximum partial discharge value, or the label characterizing the partial discharge event feature information comprises a partial discharge value, a phase, and a time of occurrence of the partial discharge event.

11. The apparatus of claim 9, wherein the data labeling processor comprises a monitoring data buffer zone and a storage data buffer zone;
the monitoring data buffer zone is configured to write a first data unit output from the data cleaning processor, and the data labeling processor reads the first data unit from the monitoring data buffer zone upon applying a label characterizing a partial discharge statistical feature to the first data unit based on a classification and labelling instruction issued by the coordination control processor within the current timing task;
the storage data buffer zone is configured to write a first data unit output from the data cleaning processor, the data labeling processor determines the partial discharge event from the first data unit read from the storage data buffer zone upon applying a label characterizing partial discharge event feature information to the current partial discharge event based on a classification and labelling instruction issued by the coordination control processor within the current timing task;
wherein, the monitoring data buffer zone comprises a first buffer zone and a second buffer zone, the first buffer zone and the second buffer zone share a read pointer and a write pointer, the direction of the write pointer and the direction of the read pointer are both switched between the first buffer zone and the second buffer zone during the switching of timing tasks; and
wherein, the storage data buffer zone comprises a third buffer zone and a fourth buffer zone, the third buffer zone and the fourth buffer zone share a read pointer and a write pointer, and the direction of the write pointer and the direction of the read pointer are both switched between the third buffer zone and the fourth buffer zone during the switching of timing tasks.

12. The apparatus of claim 9, wherein a continuous time period occupied by each timing task is provided with a dormancy period.

13. The apparatus of claim 9, wherein the timing task is divided into two tiers, the first tier of the timing task executes sampling control, transmission control and bus control on the partial discharge signal in a timing sequence, a second tier of the timing task is configured to issue a link establishment instruction, a display communication setup instruction and a data display instruction under bus control and a data cleaning instruction, a classification and labeling instruction and a data caching instruction under sampling control when the timing task is executed;
the data cleaning processor is configured to, within the current timing task, perform analog-to-digital conversion on the partial discharge signal based on a sampling control instruction issued by the sampling control to obtain a partial discharge pulse sequence, and after analog-to-digital conversion, perform data cleaning on the partial discharge pulse sequence based on a data cleaning instruction to obtain a first data unit;
the data labeling processor is configured to, within the current timing task:
write the first data unit to the monitoring data buffer zone and the storage data buffer zone based on the data caching instruction, then read the first data unit cached within the monitoring data buffer zone based on the classification and labeling instruction, apply a label characterizing a partial discharge statistical feature to the first data unit, and read the first data unit cached within the storage data buffer zone based on the classification and labeling instruction, and apply a label characterizing partial discharge event feature information to the current partial discharge event when the first data unit triggers a threshold condition for the partial discharge event;
perform data preparation for the labeled first data unit to be transmitted and the labeled partial discharge event based on the transmission control instruction;
establish a PCIE bus transmission link with the host computer and the data storage processor via an internal bus interface circuit inside based on the link establishment instruction;
establish communication with the host computer via a data display interface circuit inside based on the display communication setup instruction; and
transmit, via a data display interface circuit, the labeled first data unit to the host computer for partial discharge change trend analysis and display based on the data display instruction.

14. The apparatus of claim 9, wherein the coordination control processor is further configured to:
perform initialization and hardware drive loading in response to the partial discharge monitoring operation instruction of the host computer;
establish timing tasks, the timing task being divided into two tiers, each timing task occupying one continuous time period, and one continuous time period being denoted as tₖ˜tₚ, wherein, tₖ denotes a starting moment of partial discharge signal preprocessing, tₚ denotes the moment when the labeled first data unit is displayed by the host computer, t₁, t₂ and t₃, in turn, are three moments within the continuous time period from tₖ to tₚ, and t₁<t₂<t₃, the first tier of timing task is executed in a timing sequence, within one timing task, sampling control, transmission control and bus control are executed on the partial discharge signal in sequence, the second tier of the timing task is configured to issue a link establishment instruction, a display communication setup instruction and a data display instruction under bus control and a data cleaning instruction, a classification and labeling instruction and a data caching instruction under sampling control when the timing task is executed;
during the time period of tₖ˜t₁, issue a sampling control instruction to a data cleaning processor to enable the data cleaning processor to perform analog-to-digital conversion on the partial discharge signal based on the sampling control instruction to obtain the partial discharge pulse sequence, after analog-to-digital conversion, issue a data cleaning instruction to the data cleaning processor to enable the data cleaning processor to perform data cleaning on the partial discharge pulse sequence based on the data cleaning instruction to obtain the first data unit, and issue a data caching instruction to the data labeling processor to enable the data labeling processor to write the first data unit into the monitoring data buffer zone and the storage data buffer zone inside based on the data caching instruction;
during the time period of t₁˜t₂, issue the classification and labeling instruction to the data labeling processor to enable the data labeling processor to read the first data unit cached within the monitoring data buffer zone based on the classification and labeling instruction, and apply to the first data unit a label characterizing the partial discharge statistical feature, and read the first data unit cached within the storage data buffer zone based on the classification and labeling instruction, and when the first data unit triggers a threshold condition for a partial discharge event, apply a label characterizing partial discharge event feature information to the current partial discharge event to enable the data storage processor to receive the labeled partial discharge event and control the memory to store the partial discharge event;
at the t₂ moment, issue a transmission control instruction to the data labeling processor to enable the data labeling processor to perform data preparation for the labeled first data unit to be transmitted and the labeled partial discharge event;
at the t₂ moment, issue a link establishment instruction to the data labeling processor to enable establishment of a PCIE bus transmission link with the host computer and the data storage processor via a bus interface circuit in the data labeling processor;
at the t₂ moment, issue a display communication establishment instruction to the data labeling processor to establish communication with the host computer via a data display interface circuit in the data labeling processor;
during the time period of t₂˜t₃, perform dormancy; and
during the time period of t₃˜tₚ, issue a data display instruction to the data labeling processor to facilitate sending the labeled first data unit to the host computer via the data display interface circuit for partial discharge change trend analysis and display.

15. The apparatus of claim 8, wherein in the data synthesis processor, a first task of obtaining the first target pulse sequence and a second task of obtaining the second target pulse sequence are executed in parallel, and the parallel execution comprises writing the valid pulse sequence from the first data buffer zone and the second data buffer zone in which the valid pulse sequence is stored, respectively, for data processing.

16. The apparatus of claim 15, wherein the first data buffer zone comprises a buffer zone A and a buffer zone B; the valid pulse sequence is stored in the buffer zone A, and when the buffer zone A is full, a write data interface is switched to the buffer zone B, while the data synthesis processor reads data from the buffer zone A; and
the second data buffer zone comprises a buffer zone C and a buffer zone D; the valid pulse sequence is stored in the buffer zone C, and when the buffer zone C is full, the write data interface is switched to the buffer zone D, while the data synthesis processor reads data from the buffer zone C.

17. A system for monitoring ultra-high frequency partial discharge of a hydro-generator, wherein the system comprises:
an ultra-high frequency partial discharge sensor, mounted on a stator winding of the hydro-generator, configured to collect a partial discharge signal of the hydro-generator;
an analog-to-digital converter, configured to perform analog-to-digital conversion on the partial discharge signal to generate a partial discharge pulse sequence;
the apparatus of claim 9, configured to perform data cleaning, data processing and data storage on the partial discharge pulse sequence to obtain a first target pulse sequence for short-period partial discharge monitoring and a second target pulse sequence for long-period partial discharge change trend analysis, and configured to label a partial discharge event;
a host computer, configured to perform short-period partial discharge monitoring after acquiring the first target pulse sequence; and
a memory, configured to store the labeled partial discharge event.

18. The system of claim 17, wherein for the apparatus, the data synthesis processor and the data labeling processor are communicatively connected with the data storage processor and the host computer, respectively, via a PCIE bus.
